(19) United States
(12) Patent Application Publication
(10) Pub. No.: US 2026/0353602 A1
(43) Pub. Date: Nov. 5, 2026

(54) ELECTRONIC COMPONENT COOLING USING COOLING MANIFOLDS FOR PRESSURIZED AIR

(71) Applicant: Lam Research Corporation, Fremont, CA (US)

(72) Inventors: Andrew Borth, Newberg, OR (US); Sean M. Donnelly, Portland, OR (US)

(21) Appl. No.: 19/116,289

(22) PCT Filed: Sep. 26, 2023
(86) PCT No.: PCT/US2023/075166

§ 371 Date: Mar. 27, 2025

Related U.S. Application Data
(60) Provisional application No. 63/377,819, filed on Sep. 30, 2022.

(51) Int. Cl. H05K 7/20; H01F 27/28; H05K 1/02

(52) U.S. Cl. CPC H05K 7/20272; H01F 27/28; H05K 1/0203; H05K 2201/064

(57) ABSTRACT

Cooling systems featuring cooling manifolds with features that conform to the shape of an electrical component to be cooled are provided herein. Such cooling manifolds may be connected with a cooling fluid source, such as a clean dry air source, by flexible and/or rigid flow conduits. The cooling manifolds may have one or more outlet ports that are configured to direct cooling fluid towards one or more surfaces of the electrical component to be cooled so that the cooling fluid directly impinges on one or more surfaces thereof.

### RELATED APPLICATION(S)

An Application Data Sheet is filed concurrently with this specification as part of the present application. Each application that the present application claims benefit of or priority to as identified in the concurrently filed Application Data Sheet is incorporated by reference herein in its entirety and for all purposes.

### BACKGROUND

Semiconductor processing tools are complex systems with large numbers of different gas flow, wafer handling, and electrical components, some of which generate significant amounts of heat that must be dissipated. Discussed herein are cooling systems that may be used to more efficiently cool some such components.

### SUMMARY

Details of one or more implementations of the subject matter described in this specification are set forth in the accompanying drawings and the description below. Other features, aspects, and advantages will become apparent from the description, the drawings, and the claims.

In some implementations, an apparatus may be provided that includes one or more electrical components, one or more flow conduits, and one or more cooling manifolds. Each cooling manifold may include one or more outlet ports that are each configured such that when fluid is flowed out of that cooling manifold via that outlet port the fluid impinges upon at least a surface of at least one of the electrical components. Each cooling manifold may also include one or more internal passages that each lead to one or more of the outlet ports of that cooling manifold, the one or more internal passages of each cooling manifold may be fluidically connected with one or more inlets, each flow conduit may be fluidically connected with one of the one or more inlets, and the flow conduit may be configured to receive the fluid.

In some implementations, at least one of the outlet ports may be in fluidic communication with ambient air around the apparatus. In some further such implementations, all of the outlet ports may be in fluidic communication with ambient air around the apparatus.

In some implementations, the one or more flow conduits may be configured to be fluidically connected with a clean dry air source.

In some implementations, the one or more flow conduits may be fluidically connected with a clean dry air source.

In some implementations, the one or more cooling manifolds may include a first cooling manifold that has a first opening leading to a corresponding first blind cavity, the first blind cavity may be configured to receive a corresponding one or more first electrical components of the one or more electrical components when the one or more first electrical components are inserted through the first opening, and the first blind cavity may have a corresponding first bottom surface opposite the corresponding first opening and having one or more first outlet ports of the one or more outlet ports located thereon.

In some implementations, the one or more first electrical components may include a first inductor including a coil portion in which a conductor travels around a center axis in a helical manner, the coil portion may have a coil radius relative to the center axis, the first bottom surface may have an arcuate cross-sectional profile having a first radius larger than the coil radius, and the first opening may be sized to receive the coil portion.

In some implementations, the first blind cavity may have at least one end surface, each end surface configured to rest on the coil portion near one end or the other of the coil portion.

In some implementations, the one or more first outlet ports may include at least two first outlet ports, and the at least two first outlet ports may each be located at a different normal distance from a plane perpendicular to the center axis.

In some implementations, the at least two first outlet ports may be located at spaced-apart locations along a first axis that is parallel to the center axis.

In some implementations, the first cooling manifold may further include one or more rib walls, each rib wall located on the first bottom surface in between two of the first outlet ports that are located at spaced-apart locations along the first axis.

In some implementations, the apparatus may further include a first substrate. The first substrate may have electrical traces that are electrically connected with the first inductor, and the first opening of the first cooling manifold may be proximate the first substrate.

In some implementations, the first radius may be less than or equal to 3 mm larger than the coil radius.

In some implementations, the one or more cooling manifolds may include a second cooling manifold that has one or more second openings, each second opening leading to a corresponding second blind cavity, each second blind cavity may be configured to receive a corresponding one or more second electrical components of the one or more electrical components when the one or more second electrical components are inserted through that second opening, and each second blind cavity may have a corresponding second bottom surface opposite the corresponding second opening and having one or more second outlet ports of the one or more outlet ports located thereon.

In some implementations, each second blind cavity may have a cross-section in a plane parallel to that second blind cavity's second bottom surface that is larger than a total cross-sectional area of the corresponding one or more second electrical components for that second blind cavity in that plane.

In some implementations, the second bottom surface of each second blind cavity may be spaced apart from the corresponding one or more second electrical components in that second blind cavity by no more than a second amount in a direction perpendicular to the second bottom surface.

In some implementations, the second amount may be about 3 mm.

In some implementations, each second blind cavity may have one or more side surfaces that are spaced apart from the corresponding one or more second electrical components in that second blind cavity by no more than a third amount.

In some implementations, at least one second bottom surface may have a plurality of second outlet ports located thereon, and the plurality of second outlet ports located on the at least one second bottom surface may be arranged in a rectangular or circular array.

In some implementations, the one or more electrical components may include a third electrical component, the one or more cooling manifolds may include a third cooling manifold, the third electrical component may be a second inductor encircling at least part of the third cooling manifold, the one or more outlet ports may include a plurality of third outlet ports, and the third outlet ports may be located along an outer circumference or perimeter of the part of the third cooling manifold encircled by the third electrical component and are configured to direct fluid flowed from the third cooling manifold via the third outlet ports towards interior surfaces of the second inductor.

In some implementations, the apparatus may further include a capping structure, the capping structure preventing flow of fluid from an end region of the second inductor in a direction aligned with a center axis of the second inductor.

In some implementations, the third electrical component may be a toroidal core inductor.

In some implementations, the one or more electrical components may include one or more terminal lugs or studs, the one or more cooling manifolds may include a fourth cooling manifold that has one or more collar elements, each collar element having an opening with a corresponding one of the terminal lugs or studs extending therethrough, and each collar element may have a region in which an interior surface of that collar element is offset radially outward from the terminal lug or stud extending therethrough and which has at least one of the one or more outlet ports located therewithin.

### BRIEF DESCRIPTION OF THE DRAWINGS

Reference to the following Figures is made in the discussion below; the Figures are not intended to be limiting in scope and are simply provided to facilitate the discussion below.

FIG. 1 depicts a schematic of a cooling system in the context of a semiconductor processing tool.

FIG. 2 depicts an isometric view of an apparatus that includes an electrical component to be cooled and a cooling manifold configured to cool that electrical component.

FIG. 3 depicts the example apparatus of FIG. 2 in an exploded state.

FIG. 4 depicts a plan view of the apparatus of FIG. 2 with section lines indicating section planes for FIGS. 5-9.

FIG. 5 depicts a section view of the apparatus of FIG. 2 along the corresponding section line in FIG. 4.

FIG. 6 depicts a section view of the apparatus of FIG. 2 along the corresponding section line in FIG. 4.

FIG. 7 depicts an isometric section view of the cooling manifold of the apparatus of FIG. 2 along the corresponding section line in FIG. 4.

FIG. 8 depicts a section view of a variant of the apparatus of FIG. 2 along the corresponding section line in FIG. 4.

FIG. 9 depicts a section view of the apparatus of FIG. 8 along the corresponding section line in FIG. 4.

FIG. 10 depicts another example apparatus featuring electrical components to be cooled and a cooling manifold configured to provide such cooling.

FIG. 11 depicts the apparatus of FIG. 10 in an exploded state.

FIGS. 12 and 13 depict plan and side views of the example apparatus of FIG. 10 with section lines indicating section planes for FIGS. 14 through 16.

FIG. 14 depicts a section view of the apparatus of FIG. 10 along the corresponding section line in FIG. 12.

FIG. 15 depicts a section view of the apparatus of FIG. 10 along the corresponding section line in FIG. 12.

FIG. 16 depicts a section view of the apparatus of FIG. 10 along the corresponding section line in FIG. 13.

FIG. 17 depicts an isometric view of another example apparatus with an electrical component to be cooled and a corresponding cooling manifold.

FIG. 18 depicts an isometric exploded view of the example apparatus of FIG. 17.

FIG. 19 depicts a plan view of the example apparatus of FIG. 17 with section lines added to indicate section planes for FIGS. 20 and 21.

FIG. 20 depicts a section view of the apparatus of FIG. 17 along the corresponding section line in FIG. 19.

FIG. 21 depicts a section view of the apparatus of FIG. 17 along the corresponding section line in FIG. 19.

FIG. 22 depicts a schematic of an example cooling control system.

The above-described Figures are provided to facilitate understanding of the concepts discussed in this disclosure, and are intended to be illustrative of some implementations that fall within the scope of this disclosure, but are not intended to be limiting-implementations consistent with this disclosure and which are not depicted in the Figures are still considered to be within the scope of this disclosure.

### DETAILED DESCRIPTION

As noted above, semiconductor processing tools or chambers may be equipped with, or connected to, various components that may generate large amounts of heat and may require cooling, e.g., in order to maintain a temperature within operational limits or to prevent component failure, or to avoid potentially unsafe conditions for human operators.

Some electrical components used in semiconductor processing tools may be subjected to high electrical loads and/or currents that may result in a significant amount of waste heat being generated by such components. For example, semiconductor processing tools that provide for the generation of plasma within one or more semiconductor processing chambers thereof may include various components used to modulate or filter the electromagnetic signal that is used to spark and maintain the plasma.

For example, such systems may feature a pedestal that may be used to support a wafer within a processing chamber. The pedestal may serve as a radio-frequency (RF) electrode (or may have such an electrode embedded therewithin) that may be provided modulated electrical power that is used to generate an electrical potential across a region within the chamber in which a plasma is to be sparked and maintained. The modulated electrical power may, for example, be subjected to filtering, e.g., using one or more LC (inductor-capacitor) filters, prior to being provided to the RF electrode in order to provide electrical power at the frequency or frequencies needed to produce the desired plasma. Generally speaking, it may be desirable to locate such filters close to the RF electrodes, or generally as close as is realistically feasible, so as to minimize the exposure of the filtered electrical signal to potential sources of electrical interference during its transit to the RF electrode. This reduces the possibility of corruption of the filtered signal, which may negatively impact the generation or maintenance of the plasma within the chamber.

Various types of components may be used to provide for filtering of the electrical signal that is sent to the RF electrodes. For example, such electrical components may include inductors (so-called “air core” or “air coil” inductors and/or solid-core inductors, e.g., toroidal core inductors, ferrite core inductors, etc.), capacitors, and/or terminal lugs or studs that may be used to connect an electrical circuit having such inductors and/or capacitors to a power source (or to the RF electrodes). Such components, due to the large electrical loads that they are subjected to, may generate significant amounts of heat that may need to be dissipated in order to maintain the temperature of such components within a desired temperature range, e.g., within the operating limits of such components.

In many electronic systems in which electrical components require active cooling, such components are typically housed within an enclosure and one or more fans are then used to draw ambient air through the enclosure. Such air flow promotes convective heat transfer from the electrical components housed within the enclosure, thereby allowing the electrical components housed therein to be cooled.

There are, however, several issues with using fan-based cooling. As a first matter, it is often the case that the enclosures used have cross-sections in directions perpendicular to the flow of air from the fan(s) that are much larger than the cross-sectional area of the fan(s). Thus, absent the use of ducting or other techniques to direct the airflow from the fans, the air that is directed through the enclosure will tend to flow through the enclosure in a relatively distributed manner. This may result in the air that flows past electrical components within the enclosure flowing past the electrical components at a much lower velocity than the velocity of the air through the fan(s). If a desired flow rate of air past the electrical components is desired, it may be necessary to operate the fan(s) so as to produce a much higher flow rate in order to maintain the desired flow rate past the electrical components.

Moreover, it is often the case that heat generation within electronics enclosures is often highly localized to particular discrete electrical components, e.g., capacitors, inductors, etc., while other components, such as wiring harnesses, low-voltage processors, etc., may generate much lower amounts of heat. Moreover, the spaces within such enclosures that are empty space do not, of course, generate heat. Thus, fan-based cooling systems provide relatively inefficient (from both thermal and power-consumption perspectives) cooling-the air flow provided by the fans is generally diffuse and thus flows against the components with high heat generation rates as well as the components with low heat generation rates unless channeled and focused with ducting. Thus, some of the air flow that could be used to provide additional cooling to the high-heat-generation components may instead be directed to cooling components that generate much lower amounts of heat (and which require lower amounts of cooling. At the same time, fans in such cooling systems may need to be operated at higher flow rates in order to maintain a level of air flow through the enclosure(s) that is sufficient to cool the components within the enclosure since the flow of air within the enclosure may flow through regions of the enclosure that do not require cooling.

Another issue with fan-based cooling is that such fans typically draw air (cooling medium) into the enclosure from the surrounding ambient air, using the ambient air to cool the electrical components before then exhausting the air back into the ambient environment. In the context of cooling electrical components of semiconductor processing tools, however, the use of ambient air as a cooling fluid may be problematic since the ambient air in the vicinity of electronics enclosures on semiconductor processing tools may be at an elevated temperature as compared with “typical” ambient air, e.g., air at room temperature (~21 C/70 °F). For example, it is often the case that electronics enclosures within semiconductor processing tools are positioned in proximity to equipment that may generate a significant amount of heat, e.g., near semiconductor processing chambers that may be operated so as to process semiconductor wafers at temperatures of several hundred degrees Celsius. Electronics enclosures may also be positioned within larger enclosures of the semiconductor processing tool, or in locations that have a high density of equipment, e.g., the underside of semiconductor processing chambers, that limit ambient air flow, resulting in regions in which the flow of ambient air is largely stagnant. Thus, the “ambient” air that is in the immediate vicinity of the intakes of such enclosures may actually be much warmer than the ambient air a foot or two away from such semiconductor processing tools.

As a result, such elevated-temperature air may have a lower heat capacity than non-fabrication facility ambient air and may correspondingly be less capable of cooling electrical components. In order to compensate for such lower heat capacity, it may be necessary to operate the cooling fans at a higher fan speed to push air through the enclosure at a higher rate. This, in turn, may reduce the lifespan of the cooling fan(s), generate more noise and vibration, and consume more electrical power (to operate the fan(s)).

The use of fans as cooling solutions in enclosures used in semiconductor processing equipment may also cause vibration that may negatively impact the performance of such semiconductor processing equipment. For example, as mentioned earlier, it may be desirable to locate the electrical components used to filter the electrical signal provided to the RF electrode close to the RF electrode, or as close as feasibly possible. To that end, in some semiconductor processing systems, the enclosure housing the electrical components used to provide RF filtering functionality may be mounted in the proximity of a pedestal housing the RF electrode. For example, if a pedestal of such a semiconductor processing tool is supported within a semiconductor processing chamber of such a semiconductor processing tool by way of a stem that extends through the bottom of the semiconductor processing chamber and is connected with a vertical lift mechanism that allows the stem and pedestal to be moved vertically up-and-down relative to the semiconductor processing chamber, such an enclosure may be mounted to the stem such that the length of the electrical cables leading from electrical components used for filtering to the RF electrodes may be reduced and such that the routing of such cables does not change when the pedestal is caused to move up or down relative to the semiconductor processing chamber. Thus, the enclosure housing such electrical components may move up and down in unison with the pedestal and also be positioned relatively close to the pedestal.

If fan-based cooling is used for the enclosure in such an arrangement, however, the close mechanical coupling between the stem/pedestal and the enclosure may act to more efficiently transmit vibrations from the enclosure, e.g., generated by the fan(s), to the stem and pedestal. Such vibrations, while potentially low in magnitude, may nonetheless result in movement of the wafer supported on the pedestal relative to the pedestal over time. Even small amounts of movement of a wafer relative to the pedestal may potentially compromise the integrity of the wafer being processed, e.g., resulting in an increased defect rate. The risks of such vibrations to wafer yield will also generally increase over time, as the fan(s) being used ages and begins to experience mechanical failure. For example, the bearings used in such cooling fans will eventually start to degrade, resulting in increased levels of vibration. Moreover, there is the potential for such cooling fans to experience other types of mechanical failure that may not cause the fan to cease operation but which may drastically increase the amount of vibration output by the fan. For example, if a fan blade breaks off, either in whole or in part, the resulting loss of fan blade material may cause the fan blade to become unbalanced, resulting in an increase in vibration.

To address issues such as those discussed above, the present inventors conceived of a cooling system in which one or more individual electrical components to be cooled may be interfaced with a cooling manifold that is configured to direct a cooling fluid out of one or more outlet ports so as to impinge on, e.g., strike at a perpendicular or oblique angle, or even flow across in a co-planar or parallel manner, a surface or surfaces of each of the electrical components to be cooled. The cooling fluid is a pressurized gas, e.g., clean dry air, that may be provided via a relatively long, small-diameter flow conduit, e.g., flexible polyethylene tubing or similar material, that may be easily routed within the enclosure and used to deliver the cooling fluid to the cooling manifolds which may be positioned in very close proximity to the electrical components to be cooled. The flow conduits may, for example, be fluidically connected with internal passages within the cooling manifolds by way of corresponding inlets in the cooling manifolds. The internal passages may then convey the cooling fluid to the respective outlet port or outlet ports of the cooling manifolds. By delivering the cooling fluid directly to the electrical components that are to be cooled, the volume of cooling fluid that must be delivered to the enclosure may be greatly reduced from the volume of cooling fluid that would need to be delivered to the enclosure using a fan-based cooling system. Moreover, such cooling fluid may be supplied from, for example, a pressurized clean dry air (CDA) source (or other pressurized air source) that provides CDA to semiconductor processing tools within a semiconductor fabrication facility. For clarity, CDA refers to air that has been filtered and then subjected to a moisture removal process, e.g., by chilling the filtered air to a temperature of 40 °C in order to freeze/condense out any moisture that may be present in the air, before pumping or directing the air to one or more CDA outlets within the semiconductor fabrication facility. As the cooling fluid that is provided via the flow conduits is pressurized and contained within a sealed system (the flow conduits) until delivered to the cooling manifolds, there is no need for the enclosure to have any fans that are used to move air through the enclosure. As such, the electrical components within the enclosure may be actively cooled without requiring the use of any fans attached to the enclosure. This completely avoids the scenario in which vibrations arising from the operation of and/or degradation in the performance of such fans are communicated into the enclosure and then transmitted to the wafer via the stem and pedestal, while still allowing the enclosure to be mounted to the stem so as to be able to be close to the RF electrode and to move up and down with the pedestal without causing the cabling/electrical connections between the enclosure and the RF electrode to flex or change configuration to accommodate the movement of the pedestal.

At the same time, since the delivery of coolant fluid, e.g., CDA, can be targeted at a component level, it is possible to actively cool only the components needing cooling, as opposed to circulating cooling air through a much larger volume that includes both the components needing active cooling as well as other components that may not require cooling. Moreover, the cooling manifolds may be constructed such that there are relatively small gaps between the cooling manifolds and the electrical components that each is configured to cool, thereby reducing the volume through which the coolant fluid must flow in order to effectively cool the electrical components being cooled. As a result, the amount of coolant fluid that must be flowed into the enclosure may be significantly reduced as compared with fan-based systems; this allows the cooling fluid to be flowed into the enclosure at a much lower rate than may be required with fan-based cooling systems, thereby significantly reducing noise. The cooling fluid in such systems may also be allowed to exhaust to the ambient environment after being directed onto the electrical components to be cooled.

The use of cooling manifolds such as are discussed herein may also allow for significantly simplified monitoring systems for semiconductor processing tool health. For example, a typical enclosure for heat-generating electrical components, e.g., such as may be used to modulate an electrical signal that is to be provided to an RF electrode, will often feature multiple fans. For example, such an enclosure may, in some cases, be subdivided into two compartments, with each compartment having two fan units (one for intake, and one for exhaust). Such an enclosure may thus have four fan units. If such an enclosure were to be used in a multi-station semiconductor processing tool, e.g., a tool having 8 or 10 stations, there could easily be 32 to 40 fan units. A semiconductor processing tool having such enclosures may also include a monitoring system to track the operational status of each of the fan units in the enclosures in order to provide alerts as to any malfunctions. In order to obtain a full picture of fan unit operational status, such a system would typically need to monitor both the fan speed and the vibration level in the fan. Fan speed alone allows detection of faults that may result in the fan operating at a reduced speed or failing to turn at all but does not offer insight as to faults that may not affect fan speed but would affect vibrational output of the fan unit, e.g., a broken fan blade or other source of rotational imbalance that may cause the fan unit to exhibit undesirable vibration. Similarly, the vibration level may offer insight as to fan unit degradation that may result in increased vibrational output but may not offer insight as to the fan unit speed. Thus, in order to obtain a complete picture of the operational status of the fan units in such a semiconductor processing tool, a fan unit monitoring system for the tool might need to track data from 64 to 80 sensors (32 to 40 speed sensors and 32 to 40 accelerometers (for vibration measurement)).

The use of cooling manifolds as discussed herein allows for a much simpler monitoring system to be used-if monitoring is even desired at all. As will be apparent from the discussion above, monitoring systems for fan-based cooling systems focus on monitoring physical phenomena that originate from the moving parts of the fan units, e.g., the rotation of the fan blades or vibrations that result from the rotation of the fan blades. In cooling systems that utilize the cooling manifolds discussed herein, cooling is accomplished without the need for moving parts in or on the enclosures housing the electrical components to be cooled. As a result, there is arguably little or no need to actually monitor the performance of a cooling manifold-based cooling system at all. However, it may still be desirable to monitor the performance of such a system, e.g., to detect when a particular cooling manifold feature is potentially not delivering a desired level of cooling. For example, a cooling manifold may exhibit reduced or non-existent cooling if there is a blockage in the flow conduit that provides cooling fluid to the cooling manifold, if the flow conduit that provides cooling fluid to the cooling manifold is crimped or deformed, or if the flow conduit that provides the cooling fluid to the cooling manifold is cut or torn. All of these types of failures, however, are able to be detected at the inlet to the flow conduit that leads to the cooling manifold, e.g., by monitoring the pressure of the cooling fluid at the inlet to the flow conduit. In fan-based cooling systems, such monitoring must necessarily occur at the location of, or in proximity to, the fan unit.

It is also possible to monitor multiple different cooling manifolds that are provided cooling fluid via flow conduits supplied from a common plenum using a common sensor; this may allow for the operational state of multiple cooling manifolds to be monitored simultaneously without requiring separate sensors for each cooling manifold.

The cooling manifolds referenced above are discussed in more detail below with reference to multiple different example embodiments.

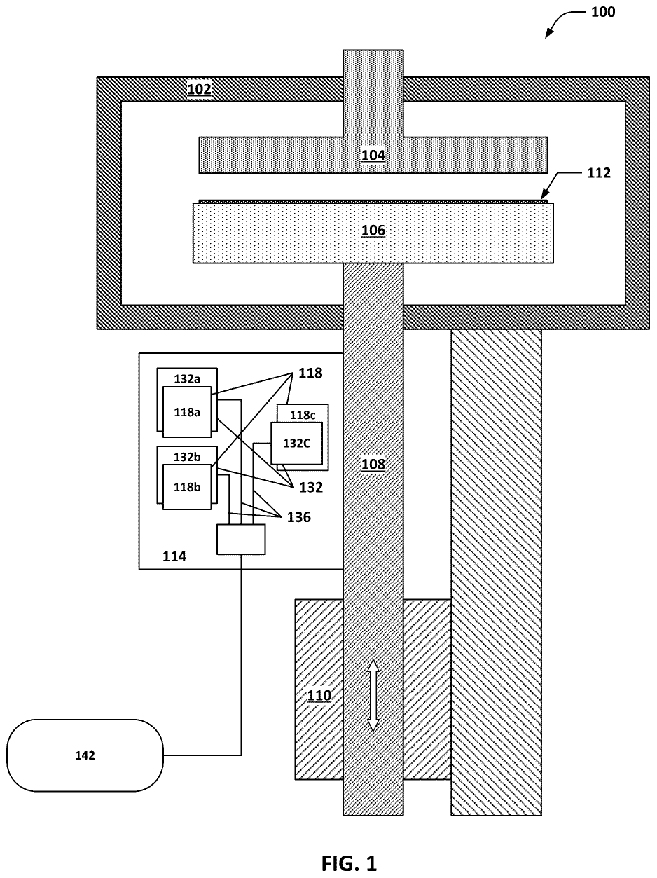

FIG. 1 depicts a schematic of an example apparatus 100, e.g., semiconductor processing tool, that includes a semiconductor processing chamber 102 that may be used in the processing of a semiconductor wafer 112. The semiconductor wafer 112 may be supported within the semiconductor processing chamber 102 by way of a pedestal 106 supported by a stem 108. The stem 108 may be connected with a vertical lift actuator 110 that may be configured to raise and lower the stem 108, the pedestal 106, and the semiconductor wafer 112 relative to the semiconductor processing chamber 102. The pedestal 106 may be positioned beneath a showerhead 104 of the semiconductor processing chamber 102 and configured so as to distribute one or more processing gases across the semiconductor wafer 112.

In some instances, the apparatus 100 may be configured so as to facilitate the striking, and maintenance, of a plasma within the space between the pedestal 106 and the showerhead 104. For example, the pedestal 106 may include an RF electrode (not shown, but may, for example, be a circular, planar layer of metallic material embedded within a ceramic body of the pedestal 106) that is provided electrical power that is routed through an electrical circuit located within an enclosure 114 prior to being delivered to the RF electrode. The enclosure, as noted above, may be affixed to, or otherwise fixed with respect to, the stem 108 such that when the stem 108 is caused to move upward or downward, the enclosure 114 and the components inside it are also able to move upward or downward.

The enclosure 114 may house various electrical components 118a/b/c (three such electrical components 118 are shown, but there may be more or fewer such electrical components) that may generate large amounts of heat and may thus require cooling. Each of the electrical components 118a/b/c may be interfaced with a corresponding cooling manifold 132a/b/c. As shown, the electrical components 118a and 118b are each at least partially housed within the corresponding cooling manifolds 132a and 132b, respectively, while the cooling manifold 132c is actually inserted within the electrical component 118c. A plurality of flow conduits 136 may direct cooling fluid to each of the cooling manifolds 132. The flow conduits 136 may be provided with the cooling fluid via a connection with a cooling fluid source, such as a CDA supply 142 that may be provided as part of a semiconductor fabrication facility, e.g., similar to how such a facility may provide infrastructure for distributing electrical power, water, purge gas, or other basic, commonly used “utilities” to different semiconductor processing tools.

The cooling manifolds 132 may be designed to have one or more surfaces that may, when the cooling manifolds 132 are interfaced with the electrical component or components 118 to be cooled, be positioned within a first minimum distance of the portion or part of the electrical component or components 118 to be cooled. Such surfaces may, for example, have generally the same shape as surfaces of the electrical component(s) to be cooled, but offset outwards (or inwards for interior surfaces of the electrical component(s) to be cooled) from the surfaces of the electrical component(s) such that a small gap exists between the surface(s) of the electrical component(s) and the surface(s) of the cooling manifold. The size of the gap may, in some cases, be on the order of a few millimeters, e.g., 3 mm, or less, e.g., 2 mm or less, 1 mm or less, 0.5 mm or less. The gap size may, in some cases, be larger than the positioning and/or size tolerance of the electrical components being cooled. Such a gap may, in some cases, be present across at least 40% of the outward-or inward-facing exterior surface area of the electrical component. In some instances, the gap may be present across at least 30%, 40%, 50%, 60%, 70%, 80%, 90%, or 100% of the exterior surface area of the electrical component.

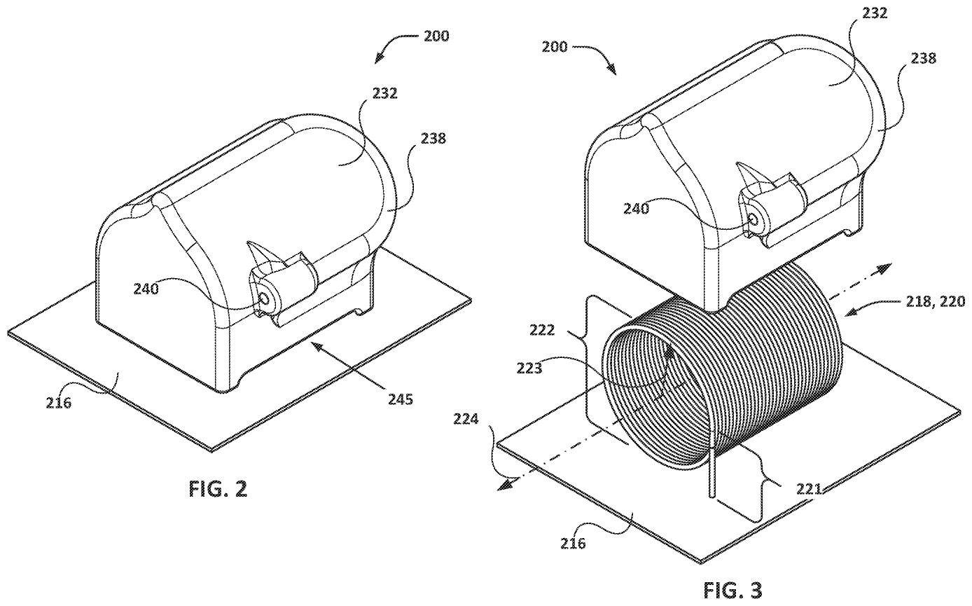

FIG. 2 depicts an example of one cooling manifold design according to the present disclosure. FIG. 3 depicts the example of FIG. 2 but in an exploded view. In FIGS. 2 and 3, a substrate 216 is shown that has mounted to it an electrical component 218 which is covered by a shroud-like cooling manifold 232. The electrical component 218 is, in this example, an air-core inductor 220. The inductor 220 includes a coil portion 222 of an electrically conductive material, e.g., copper wire, that is wound into a helical shape about a center axis 224. The coil portion 222 may have coil end segments 221 that extend downward into holes in the substrate 216, thereby allowing the inductor 220 to be mechanically and electrically joined, e.g., via soldering, to electrical traces within the substrate 216.

As can be seen, the inductor 220/electrical component 218 has the approximate shape of a cylindrical tube. Correspondingly, the cooling manifold 232 has an interior surface (not visible here, but see later Figures, e.g., FIGS. 5 through 9, for example) that is semicylindrical in shape and has a radius that is slightly larger than a coil radius 223 of the coil portion 222. The coil radius 223 may, for example, represent the radius of a reference cylinder that circumscribes the coil portion 222. The cooling manifold 232 is, at the same time, sized to allow the cooling manifold 232 to be placed over the electrical component 218/inductor 220 such that the electrical component 218/inductor 220 is covered by the cooling manifold 232. The cooling manifold 232 may, in some cases, be sized so as to rest on the substrate 216, thereby allowing the substrate to take most of the load of supporting the cooling manifold 232. In other implementations, however, the cooling manifold 232 may rest on the electrical component 218 that is to be cooled.

The cooling manifold 232, in this case, has an inlet 240 that may be configured to connect with a flow conduit (not shown) via a fitting, e.g., a push-to-connect fitting or other suitable fluidic connector. The inlet 240 may be fluidically connected within the cooling manifold 232 to an internal passage 238 (to be clear, the callout 240 in FIGS. 2 and 3 is pointing to a portion of the exterior of the cooling manifold in which the internal passage 238 is located rather than to the internal passage itself).

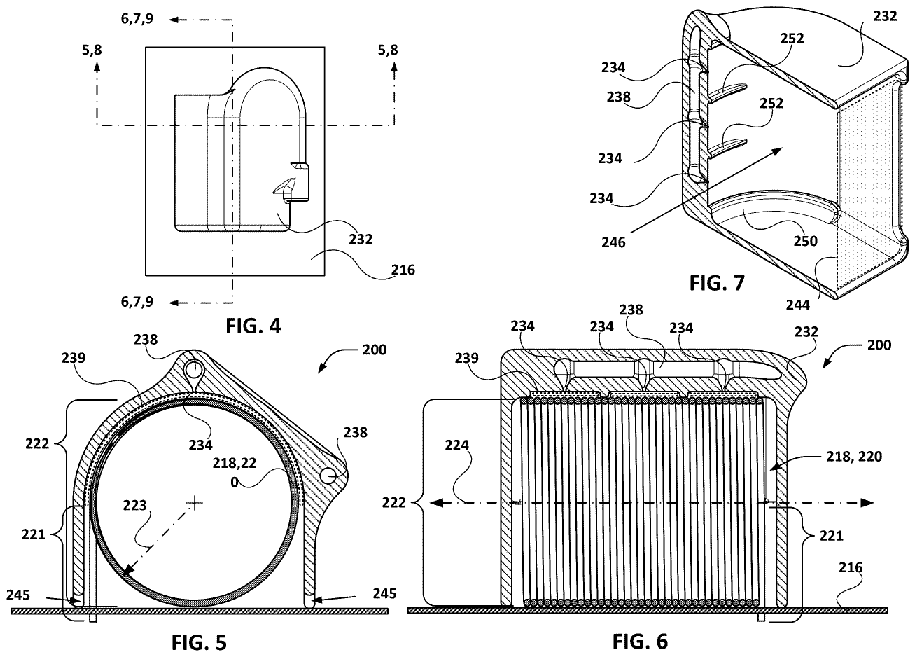

FIG. 4 depicts a plan view of the example apparatus of FIGS. 2 and 3, with section lines added to indicate the section planes for the cross-sections shown in FIGS. 5 and 6. FIG. 7 depicts an isometric view of the cooling manifold of FIG. 4 along the section line for FIG. 6 but without the substrate 216 or the electrical component 218 visible.

As can be seen in FIGS. 4 through 7, the cooling manifold 232 is designed to be placed over the electrical component 218/inductor 220 such that the electrical component 218/inductor 220 is, in effect, almost completely enclosed within a volume bounded by the cooling manifold 232 and the substrate 216. For example, the cooling manifold 232 may have an opening 244 that leads to a blind cavity 246, e.g., a cavity that is open to the surrounding environment via the opening 244 but which is otherwise generally blocked off from the surrounding environment, that is sized to receive the electrical component 218/inductor 220 when the electrical component 218/inductor 220 is inserted through the opening 244.

The blind cavity 246 of the cooling manifold 232 is generally U-shaped, featuring an arcuate or curved bottom surface having an arcuate or curved cross-sectional profile in which outlet ports 234 are located and two side surfaces that are generally tangential to the arcuate bottom surface. The arcuate bottom surface may have a radius that is somewhat larger than the coil radius 223 of the coil portion 222 of the electrical component 218/inductor 220, e.g., a radius that is less than or equal to 3 mm larger than the coil radius, e.g., between about 0.25 mm to 2.5 mm, or between 1 mm to 2 mm. Such radial differences may result in correspondingly sized gap regions between the cooling manifold and the component to be cooled; such gap regions may be optimally sized to provide enhanced cooling while at the same time being sufficiently large enough to permit reliable installation of the cooling manifold given expected variations in component size and placement. This allows the circular coil portion 222 of the electrical component 218/inductor 220 to be inserted through the opening 244 and positioned within the cooling manifold 232 so that the outer surface of the upper half of the electrical component 218/inductor 220 is within a small distance, e.g., on the order of a millimeter or several millimeters, e.g., 2.5 mm or 3 mm or less, of the surface of the cooling manifold 232 closest thereto (the arcuate bottom surface, in this case). This results in a gap region 239 being formed that extends across a significant portion of the outward-facing exterior surface of the electrical component 218/inductor 220. For example, the electrical component 218/inductor 220 has a generally cylindrical outward-facing surface defined by the coil portion 222 (the coil end segments 221, or any leads or wires that serve to connect the electrical component to be cooled with other electrical components but which otherwise are not intended to provide functionality associated with the electrical component, would not be considered to contribute to the “exterior surface” of the electrical component in question). The gap region 239 extends across at least one half of that outward-facing exterior surface, e.g., at least 40% of the outward-facing exterior surface area of the electrical component 218/inductor 220.

The cooling manifold 232 and/or substrate 216 may also have one or more exhaust openings 245 that may be located such that the electrical component 218/inductor 220 is interposed between the exhaust opening(s) 245 and the outlet ports 234. The outlet ports 234, as can be seen, are configured to direct cooling fluid, e.g., CDA, directly into the gap region 239 so that the cooling fluid impinges directly on an exterior surface of the electrical component 218/inductor 220 and then flows through the gap region 239 (and across one or more exterior surfaces of the electrical component 218/inductor 220) before exiting via the one or more exhaust openings 245. It will be understood that while the exhaust openings 245 take the form of slits defined by the substrate 216 and by portions of the bottom edge of the cooling manifold 232 that are recessed in a direction perpendicular to the substrate 216 from the remainder of the bottom edge of the cooling manifold 232, other implementations may have alternate exhaust opening configurations. For example, some implementations may utilize a series of holes in place of an elongate slit or opening. Other implementations may place such features either entirely in the cooling manifold 232 (e.g., in the sidewalls thereof) or entirely in the substrate 216.

As noted above, the cooling manifold 232 may include one or more outlet ports 234 that may be configured to direct cooling fluid from the cooling manifold 232 such that it impinges on a surface or surfaces of the electrical component 218/inductor 220. The depicted example cooling manifold 232 features a plurality of outlet ports 234, e.g., three, that are arranged at different normal distances from a reference plane that is perpendicular to the center axis 224. In this particular example, the outlet ports 234 are arranged in a linear array, e.g., along spaced-apart locations along a corresponding axis that is generally parallel to the center axis 224 of the electrical component 218/inductor 220, along the interior of the cooling manifold, e.g., along the bottom surface of the blind cavity 246. Depending on the length of the electrical component 218/inductor 220, more or fewer outlet ports 234 may be used, e.g., one outlet port 234, two outlet ports 234, or more than three outlet ports 234. In instances where there are two or more outlet ports 234, it may be desirable to direct flow through the gap region 239 in a particular manner, e.g., to encourage more uniform flow of the cooling fluid.

As noted above and as is evident from the Figures, the cooling manifold 232 has an interior surface that is generally conformal to the exterior contours of at least part of the electrical component 218/inductor 220 in the gap region 239. However, there may be some departures from such conformality, e.g., where the gap in the gap region 239 changes or even vanishes completely, that may be provided to promote a desired flow path of the cooling fluid.

For example, in the cooling manifold 232, the bottom surface of the blind cavity 246 features rib walls 252 that are each interposed between, e.g., midway between, an adjacent pair of outlet ports 234 (or between two sets of outlet ports 234). The rib walls, in this example, are generally arcuate walls that extend up from the bottom surface of the blind cavity 246 at at least their highest points by a distance that is generally the same as the thickness of the gap region at the location of the rib walls 252. Thus, when the cooling manifold 232 is placed over the electrical component 218/inductor 220 so as to form the gap region 239, the rib walls 252 may contact or almost contact the electrical component 218/inductor 220, thereby presenting a barrier to fluid flow in the axial direction in the vicinity of the rib walls 252. Such an arrangement may help manage the flow of cooling fluid from each of the outlet ports 234 through the gap region 239 such that the cooling fluid flow remains more evenly distributed.

The cooling manifold 232 also features end surfaces 250 which are each sized so as to contact the electrical component 218/inductor 220 or at least significantly reduce the gap between the cooling manifold 232 and the electrical component 218/inductor 220. The end surfaces 250 may, for example, be arcuate surfaces that are conformal to the electrical component 218/inductor 220, but which are sized to have a smaller radius than the radius of the remainder of the bottom surface of the blind cavity 246. Such end surfaces 250 may act to block, or at least hinder, the flow of cooling fluid in the axial direction with respect to the center axis 224, thereby reducing the risk that the cooling fluid (particularly from the end-most outlet ports 234) will flow over the ends of the electrical component 218/inductor 220 and into the internal cavity thereof rather than through the gap region, which may result in less efficient cooling of the electrical component 218/inductor 220.

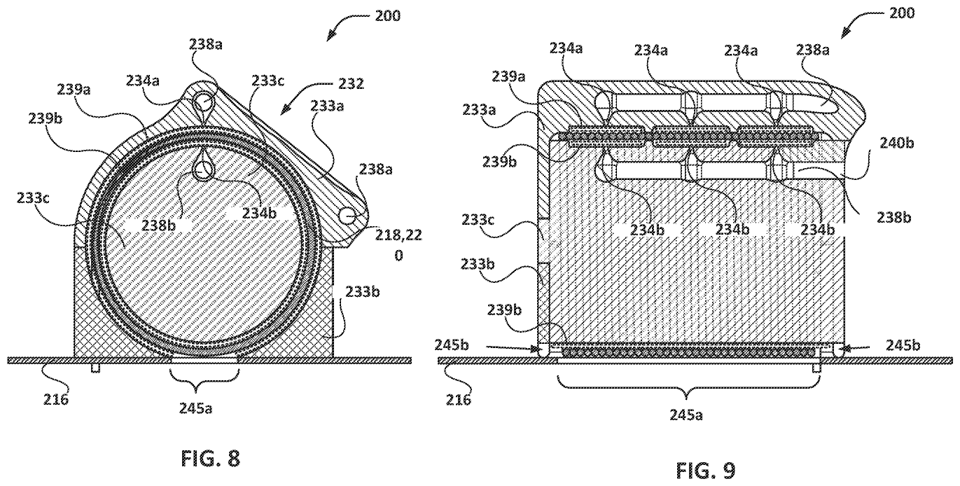

In some implementations, the cooling manifold 232 may be made from multiple pieces so as to facilitate providing a gap region that extends over a greater proportion of the outward-facing exterior surface of the electrical component 218/inductor 220. FIGS. 8 and 9 depict cross-sections (similar to the cross-sections of FIGS. 5 and 6) of a variant of the cooling manifold 232 in which there are three portions 233a, 233b, and 233c. The portion 233a is similar to the top half of the cooling manifold 232 of FIGS. 5 and 6 and includes an internal passage 238a and outlet ports 234a that direct cooling fluid into a gap region 239a. The portion 233b has an interior surface that mimics that of the portion 233a, but facing in the opposite direction. The portion 233b may, for example, have a semicircular trough in it that is sized to receive the electrical component 218/inductor 220 while still preserving the gap region 239a between the electrical component 218/inductor 220 and the portion 233b. The portion 233b may, for example, have a through-slot along its length at the bottom of the trough that may be aligned with a corresponding slot in the substrate 216, thereby providing an exhaust opening 245a. In some instances, the portion 233b may actually be a two-piece assembly, e.g., split down the middle in the axial direction so that each half may be slid in a direction parallel to the substrate 216 and under the electrical component 218/inductor 220, thereby allowing the portion 233b to be installed after the electrical component 218/inductor 220 is already connected to the substrate 216. As can be seen, such an arrangement has the effect of extending the gap region 239a around almost the entire circumference of the coil portion 222 of the electrical component 218/inductor 220. This may extend the cooling capability of the cooling manifold 232 such that it cools both the top and bottom of the electrical component 218/inductor 220 with generally similar efficacy.

The portion 233c in this example is a solid (or tubular) insert that is sized to be able to be inserted within the electrical component 218/inductor 220. The portion 233c may be sized to be slightly smaller than the interior diameter of the electrical component 218/inductor 220, thereby allowing a second gap region 239b to be formed between the inward-facing exterior surface of the electrical component 218/inductor 220 and the portion 233c. The portion 233c may similarly be provided with an internal passage 238b that provides cooling fluid to one or more outlet ports 234b that direct cooling fluid onto an inward-facing surface of the electrical component 218/inductor 220. The cooling fluid may then flow through the additional gap region 239b towards the substrate 216. As the structure of the electrical component 218/inductor 220 may block flow of the cooling fluid to the exhaust opening 245a, the portion 233b may be equipped with features forming additional exhaust openings 245b in opposing ends of the cooling manifold 232 to allow cooling fluid to escape out of the cooling manifold 232 in directions parallel to the center axis 224.

It will be understood that a cooling manifold such as the cooling manifold 232 may be provided via a single-piece design or a multi-piece design, and with or without an internal cooling portion, e.g., such as the portion 233c.

It will be further understood that while the inductor 220 used in the above examples features a coil portion in which the inductor wire is helically wound with a pitch that is equal to the inductor wire diameter so that each winding of the inductor wire is in contact with the adjacent winding or windings of the inductor wire (thus effectively forming a solid-wall tube), similar cooling manifolds may be used with inductors in which the windings are wound with a pitch that is greater than the diameter of the inductor wire such that an axial gap exists between adjacent windings of the inductor wire, thereby allowing for radial flow past the inductor wire.

Other electrical components that may require cooling may be of different form factors from the electrical component 218/inductor 220. For example, some electrical components may have packaging envelopes that are prismatic solids or tapered prismatic solids; such electrical components may be mounted to a substrate, e.g., via soldering, and then covered with a cooling manifold that has one or more pockets or recessed in the underside that are positioned and sized so as to each receive one or more of the electrical components when the cooling manifold is placed against the substrate.

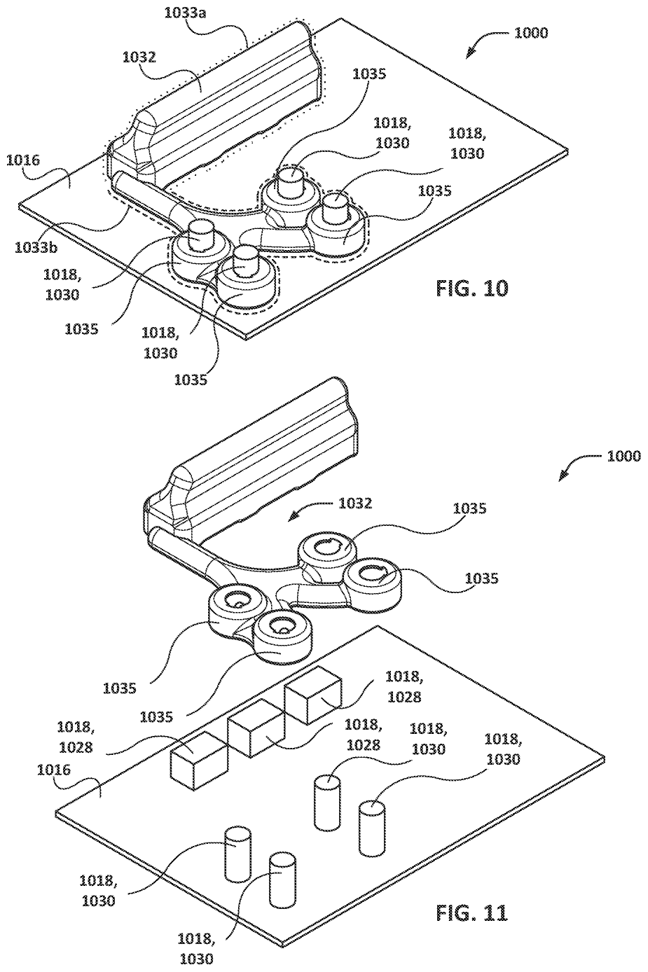

FIGS. 10 and 11 depict isometric and exploded isometric views, respectively, of an example apparatus featuring surface-mount electrical components and a cooling manifold configured to direct cooling fluid onto such components.

As visible in FIGS. 10 and 11, a substrate 1016 is provided that has mounted thereto a plurality of electrical components 1018. The electrical components 1018 are, in this example, surface-mount capacitors 1028 and terminal lugs or studs 1030. The terminal lugs or studs 1030 may, for example, be threaded or unthreaded studs (either externally or internally threaded) that are designed to allow high-voltage electrical connections to be made.

Also visible in FIGS. 10 and 11 is a cooling manifold 1032. The cooling manifold 1032 has two distinct portions 1033a and 1033b that are shown as a single, integrated part, but it will be understood that either portion may be provided as a separate, standalone cooling manifold.

A first portion 1033a of the cooling manifold 1032 is generally rectangular in footprint and is designed to cover surface-mount electrical components such as the capacitors 1028. Of course, if the surface mount component(s) to be cooled are arranged differently from as shown (e.g., in a line), the footprint of this portion may be adjusted to match. Generally speaking, the footprint of such a cooling manifold may fully enclose the various electrical components to be cooled and may be sized large enough that a gap exists between the outer perimeter of this portion of the cooling manifold and the electrical components to be cooled.

A second portion 1033b of the cooling manifold 1032 includes a system of branching passages that each lead to a different collar element 1035. The collar elements 1035 in this example are intended to encircle, but not necessarily cap, the terminal lugs or studs 1030. Cooling fluid may be directed to the collar elements 1035 via the branching passages.

When the cooling manifold 1032 is interfaced with the electrical components 1018/capacitors 1028 or terminal lugs or studs 1030, the bottom of the cooling manifold 1032 may be pressed against the substrate 1016, enclosing the capacitors 1028 between the substrate 1016 and the cooling manifold 1032.

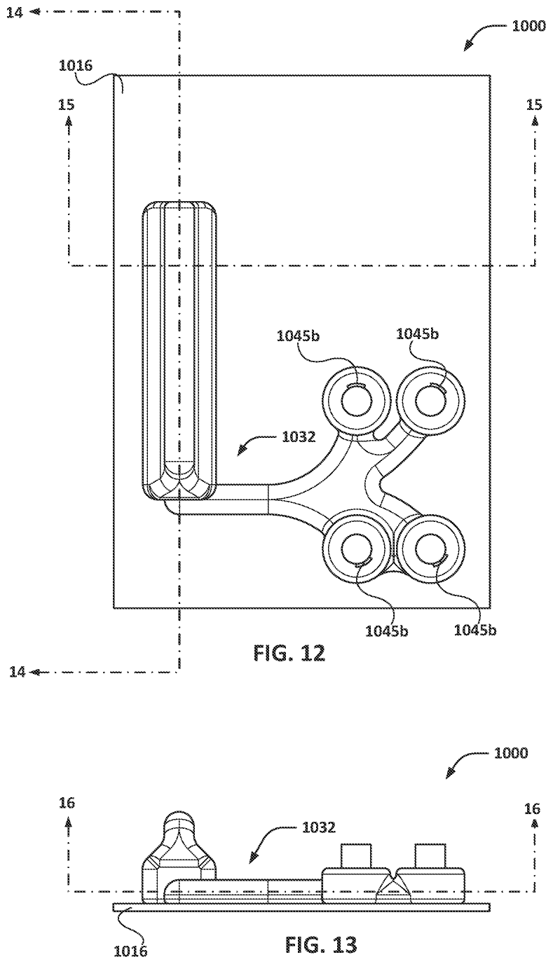

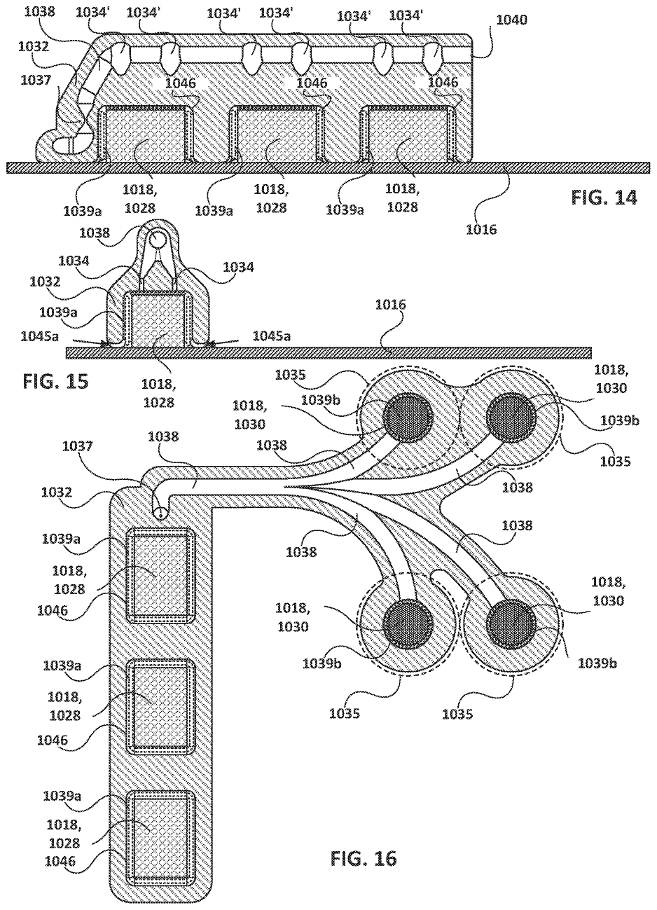

FIGS. 12 and 13 are plan and side views, respectively, of the apparatus of FIGS. 10 and 11 that show section lines used for FIGS. 14, 15, and 16, which are discussed below.

FIG. 14 shows a section view through the first portion 1033a of the cooling manifold 1032 along its long axis, while FIG. 15 shows a section view through the first portion 1033a of the cooling manifold 1032 along its transverse axis. FIG. 16 depicts a section view of the cooling manifold 1032 in a plane parallel to, and somewhat offset from, the substrate 1016.

As can be seen in FIGS. 14 and 15, the first portion 1033a of the cooling manifold 1032 has a series of openings (not marked) that each lead to a blind cavity 1046. The blind cavities 1046 are each positioned in a location that aligns with one of the capacitors 1028 such that when the first portion 1033a of the cooling manifold 1032 is placed over the capacitors 1028, each capacitor 1028 is received by a corresponding blind cavity 1046. Each blind cavity 1046 is sized such that a gap region 1039a exists between one or more surfaces thereof and one or more exterior surfaces of the capacitor 1028 received therewithin (or any other electrical component that is to be received in that blind cavity 1046). Each gap region 1039a in this example extends across five sides of the corresponding capacitor 1028. The gap region 1039a may, as shown vary in thickness due to factors such as variation in the size of the capacitors 1028 and variation in the locations of the capacitors 1028 relative to one another and the substrate 1016 due to how accurately the capacitors 1028 were positioned when soldered into place on the substrate 1016. However, the gap region 1039a may generally be small in size, e.g., similar to the dimensions mentioned above.

It will generally be observed that each blind cavity 1046 has a shape that is generally conformal to, although with an outward offset from, the shape of the electrical component received thereby. This offset defines the gap region 1039a that is provided within the blind cavity 1046 to facilitate flow of the cooling fluid.

In the depicted example, each of the blind cavities 1046 is provided cooling fluid by a set of four outlet ports 1034 that are arranged in a circular or rectangular array so as to evenly distribute the cooling fluid across the electrical component 1018 being cooled (in FIG. 14, locations 1034′ indicate antechambers that each lead to two outlet ports 1034 that are positioned on opposing sides of the section plane of FIG. 14). Fewer or more outlet ports 1034 may be provided for each blind cavity 1046, of course, depending on the fluid flow rate needed and/or the size of the outlet ports. Generally speaking, the outlet ports may be sized so as to have a cross-sectional area that is at least 10 times smaller than the cross-sectional area of the internal passage that supplies them with cooling fluid in order to help maintain adequate back pressure and relatively equal distribution of cooling fluid to each outlet port 1034. Alternatively, equivalent flow restrictions may be placed in the internal passage itself, e.g., as shown by flow restrictor 1037, which is located in the internal passage 1038 such that it is fluidically interposed between the outlet ports 1034 and the collar elements 1035 that are used to cool the terminal lugs or studs 1030. The cooling fluid provided by the outlet ports 1034 may, after flowing through the gap regions 1039a, flow out of the cooling manifold 1032 via exhaust openings 1045a. The exhaust openings 1045a, for example, may be similar to the exhaust openings 245 discussed earlier, e.g., provided by holes or slits in the substrate 1016 and/or cooling manifold 1032 or by, as show in FIG. 15, providing recesses in the bottom edge of the cooling manifold 1032 that, when the cooling manifold 1032 is placed against the substrate 1016, result in a slit-like gap between the bottom edge of the cooling manifold 1032 and the substrate 1016.

The collar elements 1035 may, as noted above, be arranged such that each collar element 1035 encircles a different terminal lug or stud 1030. The collar elements 1035 may, for example, each have an internal diameter that is sized larger than the diameter of the corresponding terminal lug or stud 1030 that each is designed to encircle, thereby creating an annular gap region 1039b around the terminal lug or stud 1030 through which cooling fluid may be flowed in order to cool that terminal lug or stud 1030. The substrate 1016 may act to cap one end of the gap regions 1039b and constrain the cooling fluid to flow around the circumferences of the terminal lugs or studs 1030. The other ends of the gap regions 1039b may be capped by flange or shoulder portions of the collar elements 1035 that extend radially inward to diameters that are smaller than the diameters of the collar elements 1035 where the gap regions 1039b exist. The flange or shoulder portions of the collar elements thus act in a similar manner to the substrate in that they hinder axial flow of the cooling fluid and constrain the cooling fluid to flow around the terminal lugs or studs 1030 in a circumferential manner. The gap region 1039b of each collar element 1035 may be fluidically connected with a corresponding internal passage 1038, e.g., via an opening (which may act as an outlet port) in the surface of the collar element 1035 that defines the outer boundary of that gap region 1039b, so that cooling fluid from the internal passage 1038 may be delivered to the gap region 1039b.

The flange or shoulder portions may, for example, have notches or gaps in them in locations generally opposite where the internal passages 1038 fluidically connect with the gap regions 1039b. Such gaps or notches may thus act as exhaust openings 1045b that allow the cooling fluid that flows around the terminal lugs or studs 1030 to exit the collar elements 1035, thereby maintaining a constant flow of cooling fluid past the terminal lugs or studs 1030.

In the above examples, the cooling manifolds have been designed such that the electrical component(s) to be cooled are insertable into a blind cavity of the cooling manifold that has one or more outlet ports for flowing cooling fluid directly onto a surface or surfaces of the electrical component(s). When such cooling manifolds are placed against a substrate to which such electrical component(s) are attached, the electrical component(s) in question are effectively fully enclosed within a chamber defined by the substrate and the cooling manifolds, with only limited openings present, e.g., outlet ports for providing cooling fluid to the chamber and exhaust openings for exhausting the cooling fluid from the chamber.

However, as noted earlier with respect to FIG. 1, some cooling manifolds may be designed to be inserted into the electrical components they are intended to cool. The implementation of FIGS. 8 and 9 actually featured such a cooling manifold, but depicted as part of a cooling manifold designed to fully enclose the electrical component to be cooled.

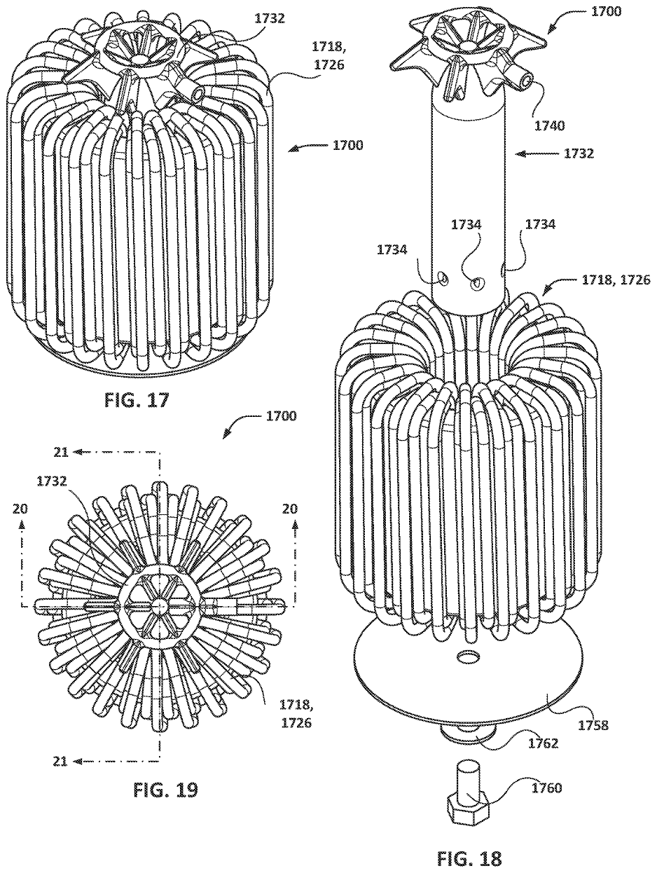

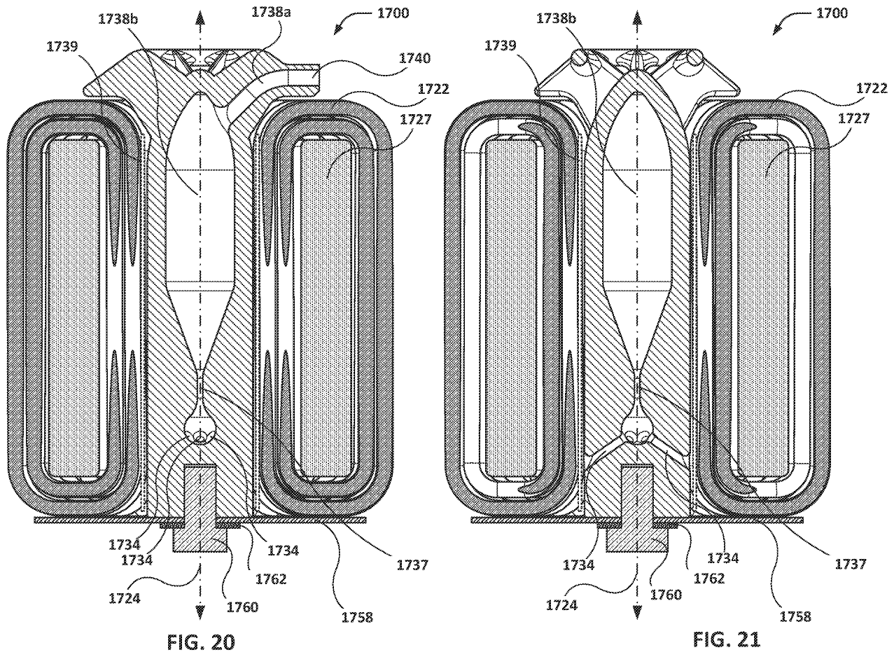

FIG. 17 depicts an example of an electrical component, e.g., a toroidal inductor, with a cooling manifold designed to be inserted into the electrical component. FIG. 18 depicts the example apparatus of FIG. 17 in an exploded state. FIG. 19 depicts a top view of the example apparatus of FIG. 17 with section lines indicating the sectioning planes for FIGS. 20 and 21. FIG. 20 depicts a section view of the example apparatus of FIG. 17 along the section line 20 in FIG. 19, while FIG. 21 depicts a section view of the example apparatus of FIG. 17 along the section line 21 in FIG. 19.

As can be seen in FIGS. 17 through 21, an apparatus 1700 is shown that includes an electrical component 1718, e.g., a toroidal solid-core inductor 1726, that may feature a tubular or toroidal core 1727 that is made of, for example, a ferrous material. A coil portion 1722 of the toroidal inductor 1726 may be provided by wrapping a conductor, e.g., copper wire, around the toroidal core such that the wire forms an inductor coil that follows a circular path defined by the toroidal core 1727. The toroidal inductor 1726 may thus have an overall shape that is tubular or annular in form, with a cylindrical open space located in the middle.

As can be seen in FIG. 18, a cooling manifold 1732 is provided that is sized and shaped so as to be inserted, at least in part, into the center of the toroidal inductor 1726. For example, a portion of the cooling manifold 1732 is cylindrical in nature and has a diameter that is slightly less than the minimum internal diameter of the toroidal inductor 1726. This allows the cylindrical part of the cooling manifold 1732 to be inserted into the cylindrical open space of the toroidal inductor 1726.

The cooling manifold 1732 may, as is visible in FIGS. 20 and 21, have an internal passage 1738a that expands into a larger antechamber-like internal passage 1738b within the cooling manifold 1732 before passing through a flow restrictor 1737 and then being distributed between outlet ports 1734. The outlet ports 1734 may be positioned in a circular array about a center axis of the toroidal inductor 1726 so as to direct cooling fluid from the internal passage 1738b into an annular gap region 1739 between the cooling manifold 1732 and the coil portion 1722 of the toroidal inductor 1726.

If desired, one end of the toroidal inductor 1726 may be capped by a capping structure 1758 or similar end structure, e.g., an end plate, that may serve to prevent or hinder fluid flow from the interior region of the toroidal inductor 1726 along the center axis 1724 of the toroidal inductor 1726 in one direction. The capping structure 1758 in this example is coupled to the cooling manifold 1732 by way of a threaded fastener 1760 and a washer 1762; the threaded fastener 1760 may be inserted through the washer 1762 and the capping structure 1758 and threaded into a threaded hole in the end of the cooling manifold 1732. In some instances, a sealant, e.g., silicone or other flowable gap-filler/adhesive, may be flowed into the space between the toroidal core 1727 and the capping structure 1758 so as to fill the gaps between the windings of the coil portion 1722 in that space, thereby more effectively sealing it.

As will be apparent from the above-discussed examples, cooling manifolds that implement the concepts discussed herein may be designed to have at least a portion of which that is generally conformal to a portion of an electrical component to be cooled-sized so as to fit over, or fit within, such an electrical component such that one or more surfaces of the electrical component are within a minimum distance of a surface or surfaces of the cooling manifold that are closest thereto (but not touching each other), thereby forming one or more gap regions between the electrical component being cooled and the cooling manifold providing the cooling. Such gap regions may be quite small and may serve to constrain the air flow around the electrical component (or at least the portion thereof over which the gap region(s) exists) such that all or almost all of the air that flows through the gap region is effective in providing cooling to the component to be cooled (whereas only a fraction of the air that is flowed through enclosures using fan-based cooling is typically effective in providing cooling). Such cooling manifolds may each be provided a cooling fluid, such as CDA, via a flexible, rigid, or combination of flexible and rigid flow conduits. This allows for targeted, direct-impingement cooling of select electrical components, greatly increasing the cooling efficiency as compared with fan-based cooling systems, reducing system noise, and simplifying the monitoring of the cooling system.

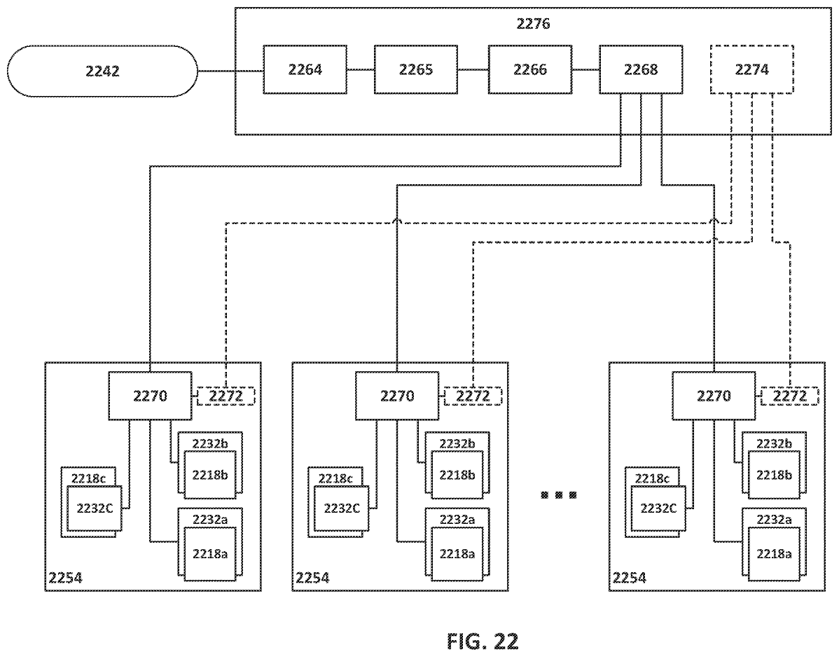

FIG. 22 depicts a schematic of an example cooling control system using the concepts discussed herein. As shown in FIG. 22, a plurality of enclosures 2254 are depicted. Each enclosure houses multiple electrical components to be cooled, e.g., electrical components 2218a/b/c. Each enclosure also houses multiple cooling manifolds 2232, e.g., cooling manifolds 2232a/b/c, that are each fluidically connected with an enclosure manifold 2270 by a separate flow conduit, e.g., length of flexible and/or rigid tubing. Each enclosure manifold 2270 is fluidically connected with a corresponding pressure sensor 2272. The enclosure manifolds 2270 are also all fluidically connected with a distribution manifold 2268 that is located in a cooling control system 2276. Cooling fluid, e.g., CDA, may be provided to the cooling control system 2276 from a CDA source 2242, e.g., a facility CDA source. The cooling fluid may be flowed through a pressure regulator 2264 in order to regulate the maximum downstream pressure of the cooling fluid and then through a valve 2265 that may be used to turn on/off coolant flow. The cooling fluid may then be flowed through a flow meter 2266 to monitor the amount of cooling fluid being flowed before being provided to the distribution manifold 2268, which may then distribute the cooling fluid to different enclosures 2254. Alternatively, other types of flow rate sensors may be used as well as or in place of such flow meters, e.g., using pressure sensors that obtain pressure measurements at two different locations along a venturi tube (such as at a first port that is located at the smallest diameter of the venturi tube and at a second port that is located upstream of the first port and in the largest diameter of the venturi).

The cooling control system may also include a multi-channel pressure monitoring system 2274 that may be communicatively connected with the pressure sensors 2272, thereby allowing pressure data from the pressure sensors 2272 to be monitored over time. As noted earlier, if the pressure measured at a particular enclosure manifold 2270 changes from a predetermined baseline or steady-state level, this may indicate a fault condition that the cooling control system 2276 may flag via a notification or alarm. For example, if the pressure in an enclosure manifold 2270 starts to increase, this may indicate a blockage in one or more of the cooling manifolds 2232 (or flow conduits leading thereto) within the associated enclosure 2254. Similarly, if the pressure in an enclosure manifold 2270 starts to decrease, this may indicate that a flow conduit has detached, ruptured, or been cut and the cooling control system may similarly send out a notification or alarm indicating the potential fault condition.

The cooling manifolds discussed herein may be made from any suitable material, although an electrically non-conductive material, such as a polymer, may be preferable to avoid the risk of electrical short-circuit. In particular, such cooling manifolds may, in some cases, be made from high-temperature plastic, e.g., a plastic that is flame-retardant and resistant to temperatures of at least 100 °C. If desired, such manifolds may be made using additive manufacturing techniques, e.g., 3D printing.

As noted above, the cooling systems discussed herein may be controlled with a cooling control system, such as that discussed above with respect to FIG. 22. Such a cooling control system may, for example, be communicatively linked with, or even part of, a larger controller or control system, e.g., for controlling one or more semiconductor processing tools and/or chambers having the cooling system(s).

The systems discussed above may be integrated with electronics for controlling their operation before and after processing of a semiconductor wafer or substrate. The electronics may be referred to as the “controller,” which may control various components or subparts of the system or systems. The controller, depending on the processing requirements and/or the type of system, may be programmed to control any of the systems disclosed herein, including operation of the various valves that may control the flow of cooling fluid, operation of other valves and/or pumps that may control the evacuation of gas so as to draw a vacuum, operation of heater elements within a pedestal assembly, the operation of various valves that may control the flow of process gases, the operation of vertical lift mechanisms for moving pedestal assemblies and/or showerheads and/or lift pins up and down, the operation of electrostatic chucks or clamping electrodes, or various other components that may be included in, or provided in association with, cooling systems as described herein.

Broadly speaking, the controller may be defined as electronics having various integrated circuits, logic, memory, and/or software that receive instructions, issue instructions, control operation, enable cleaning operations, enable endpoint measurements, and the like.

The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular operation using a cooling system as described herein.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits in enclosures housing components to be cooled (such as integrated circuits that are part of a pressure sensor system) in communication with one or more integrated circuits located remotely (such as at the platform level or as part of a remote computer) that combine to monitor the operation of a cooling system as described herein.

Without limitation, cooling systems as described herein may be connected with one or more other pieces of equipment, including a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, or any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers, e.g., FOUPs, to and from tool locations and/or load ports in a semiconductor manufacturing factory.

For the purposes of this disclosure, the term “fluidically connected” is used with respect to volumes, plenums, holes, etc., that may be connected with one another, either directly or via one or more intervening components or volumes, in order to form a fluidic connection, similar to how the term “electrically connected” is used with respect to components that are connected together to form an electric connection. The term “fluidically interposed,” if used, may be used to refer to a component, volume, plenum, or hole that is fluidically connected with at least two other components, volumes, plenums, or holes such that fluid flowing from one of those other components, volumes, plenums, or holes to the other or another of those components, volumes, plenums, or holes would first flow through the “fluidically interposed” component before reaching that other or another of those components, volumes, plenums, or holes. For example, if a pump is fluidically interposed between a reservoir and an outlet, fluid that flowed from the reservoir to the outlet would first flow through the pump before reaching the outlet. The term “fluidically adjacent,” if used, refers to placement of a fluidic element relative to another fluidic element such that there are no potential structures fluidically interposed between the two elements that might potentially interrupt fluid flow between the two fluidic elements. For example, in a flow path having a first valve, a second valve, and a third valve placed sequentially therealong, the first valve would be fluidically adjacent to the second valve, the second valve fluidically adjacent to both the first and third valves, and the third valve fluidically adjacent to the second valve.

The use, if any, of ordinal indicators, e.g., (a), (b), (c) . . . or (1), (2), (3) . . . or the like, in this disclosure and claims is to be understood as not conveying any particular order or sequence, except to the extent that such an order or sequence is explicitly indicated. For example, if there are three steps labeled (i), (ii), and (iii), it is to be understood that these steps may be performed in any order (or even concurrently, if not otherwise contraindicated) unless indicated otherwise. For example, if step (ii) involves the handling of an element that is created in step (i), then step (ii) may be viewed as happening at some point after step (i). Similarly, if step (i) involves the handling of an element that is created in step (ii), the reverse is to be understood. It is also to be understood that use of the ordinal indicator “first” herein, e.g., “a first item,” should not be read as suggesting, implicitly or inherently, that there is necessarily a “second” instance, e.g., “a second item.” It should also be understood that the use of an ordinal indicator that would typically follow a lower-valued or lower-ranked ordinal indicator should not be read as requiring that a similar element with the lower-valued or lower-ranked ordinal indicator be present. For example, if a claim refers to a “second item” but there is no mention of a “first item” in the claim (or its parent claim(s), if a dependent claim), this should not be read to mean that the claim also implicitly includes a “first item” within its scope.

It is to be understood that the phrases “for each <item> of the one or more <items>,” “each <item> of the one or more <items>,” or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite the fact that dictionary definitions of “each” frequently define the term to refer to “every one of two or more things”) and would not imply that there must be at least two of those items. Similarly, the term “set” or “subset” should not be viewed, in itself, as necessarily encompassing a plurality of items-it will be understood that a set or a subset can encompass only one member or multiple members (unless the context indicates otherwise).

The term “between,” as used herein and when used with a range of values, is to be understood, unless otherwise indicated, as being inclusive of the start and end values of that range. For example, between 1 and 5 is to be understood to be inclusive of the numbers 1, 2, 3, 4, and 5, not just the numbers 2, 3, and 4.

The term “operatively connected” is to be understood to refer to a state in which two components and/or systems are connected, either directly or indirectly, such that, for example, at least one component or system can control the other. For example, a controller may be described as being operatively connected with a resistive heating unit, which is inclusive of the controller being connected with a sub-controller of the resistive heating unit that is electrically connected with a relay that is configured to controllably connect or disconnect the resistive heating unit with a power source that is capable of providing an amount of power that is able to power the resistive heating unit so as to generate a desired degree of heating. The controller itself likely cannot supply such power directly to the resistive heating unit due to the currents involved, but it will be understood that the controller is nonetheless operatively connected with the resistive heating unit.

It is understood that the examples and implementations described herein are for illustrative purposes only and that various modifications or changes in light thereof will be suggested to persons skilled in the art. Although various details have been omitted for clarity's sake, various design alternatives may be implemented. Therefore, the present examples are to be considered as illustrative and not restrictive, and the disclosure is not to be limited to the details given herein but may be modified within the scope of the disclosure.

It is to be understood that the above disclosure, while focusing on a particular example implementation or implementations, is not limited to only the discussed example, but may also apply to similar variants and mechanisms as well, and such similar variants and mechanisms are also considered to be within the scope of this disclosure.

1. An apparatus comprising:
one or more electrical components;
one or more flow conduits; and
one or more cooling manifolds, wherein:
each cooling manifold comprises one or more outlet ports, wherein each outlet port is configured such that when fluid is flowed out of that cooling manifold via that outlet port the fluid impinges upon at least a surface of at least one of the electrical components,
each cooling manifold also comprises one or more internal passages, wherein each internal passage leads to one or more of the outlet ports of that cooling manifold,
the one or more internal passages of each cooling manifold are fluidically connected with one or more inlets,
each flow conduit is fluidically connected with one of the one or more inlets, and
the flow conduit is configured to receive the fluid.

2. The apparatus of claim 1, wherein at least one of the outlet ports is in fluidic communication with ambient air around the apparatus.

3. (canceled)

4. The apparatus of claim 1, wherein the one or more flow conduits are configured to be fluidically connected with a clean dry air source or are connected with a clean dry air source.

5. (canceled)

6. The apparatus of claim 1, wherein:
the one or more cooling manifolds comprise a first cooling manifold that has a first opening leading to a corresponding first blind cavity,
the first blind cavity is configured such that a corresponding one or more first electrical components of the one or more electrical components are insertable therein, and
the first blind cavity has a corresponding first bottom surface opposite the corresponding first opening, and
one or more first outlet ports of the one or more outlet ports are located on the first bottom surface.

7. The apparatus of claim 6, wherein:
the one or more first electrical components comprise a first inductor including a coil portion in which a conductor travels around a center axis in a helical manner,
the coil portion has a coil radius relative to the center axis,
the first bottom surface has an arcuate cross-sectional profile having a first radius larger than the coil radius, and
the first opening is sized to receive the coil portion.

8. The apparatus of claim 7, wherein the first blind cavity has at least one end surface, each end surface configured to rest on the coil portion near one end or the other of the coil portion.

9. The apparatus of claim 7, wherein:
the one or more first outlet ports comprise at least two first outlet ports, and
the at least two first outlet ports are each located at a different normal distance from a plane perpendicular to the center axis.

10. The apparatus of claim 9, wherein the at least two first outlet ports are located at spaced-apart locations along a first axis that is parallel to the center axis.

11. The apparatus of claim 10, wherein the first cooling manifold further comprises one or more rib walls, each rib wall located on the first bottom surface in between two of the first outlet ports that are located at spaced-apart locations along the first axis.

12. The apparatus of claim 7, further comprising a first substrate, wherein:
the first substrate has electrical traces that are electrically connected with the first inductor, and
the first opening of the first cooling manifold is proximate the first substrate.

13. (canceled)

14. The apparatus of claim 1, wherein:
the one or more cooling manifolds comprise a second cooling manifold that has one or more second openings, each second opening leading to a corresponding second blind cavity,
each second blind cavity is configured such that a corresponding one or more second electrical components of the one or more electrical components are insertable therein,
each second blind cavity has a corresponding second bottom surface opposite the corresponding second opening, and
one or more second outlet ports of the one or more outlet ports are located on the second bottom surface.

15. The apparatus of claim 14, wherein each second blind cavity has a cross-section in a plane parallel to that second blind cavity's second bottom surface that is larger than a total cross-sectional area of the corresponding one or more second electrical components for that second blind cavity in that plane.

16. The apparatus of claim 15, wherein the second bottom surface of each second blind cavity is spaced apart from the corresponding one or more second electrical components in that second blind cavity by no more than a second amount in a direction perpendicular to the second bottom surface.

17. The apparatus of claim 16, wherein the second amount is 2.5 mm.

18. The apparatus of claim 15, wherein each second blind cavity has one or more side surfaces that are spaced apart from the corresponding one or more second electrical components in that second blind cavity by no more than a third amount.

19. The apparatus of claim 14, wherein:
at least one second bottom surface has a plurality of second outlet ports located thereon, and
the plurality of second outlet ports located on the at least one second bottom surface is arranged in a rectangular or circular array.

20. The apparatus of claim 14, wherein:
the one or more electrical components comprises a third electrical component,
the one or more cooling manifolds comprise a third cooling manifold,
the third electrical component is a second inductor encircling at least part of the third cooling manifold,
the one or more outlet ports comprises a plurality of third outlet ports, and
the third outlet ports are located along an outer circumference or perimeter of the part of the third cooling manifold encircled by the third electrical component and are configured to direct fluid flowed from the third cooling manifold via the third outlet ports towards interior surfaces of the second inductor.

21. The apparatus of claim 20, further comprising a capping structure, the capping structure preventing flow of fluid from an end region of the second inductor in a direction aligned with a center axis of the second inductor.

22. The apparatus of claim 21, wherein the third electrical component is a toroidal core inductor.

23. The apparatus of claim 22, wherein:
the one or more electrical components comprises one or more terminal lugs or studs,
the one or more cooling manifolds comprise a fourth cooling manifold that has one or more collar elements, each collar element having an opening with a corresponding one of the terminal lugs or studs extending therethrough, and
each collar element has a region in which an interior surface of that collar element is offset radially outward from the terminal lug or stud extending therethrough and which has at least one of the one or more outlet ports located therewithin.
